(19) United States
(12) Patent Application Publication
(10) Pub. No.: US 2008/0038866 A1
(43) Pub. Date: Feb. 14, 2008

(54) METHOD FOR FABRICATING ACTIVE MATRIX ORGANIC ELECTRO-LUMINESCENCE DISPLAY PANEL

(75) Inventor: Yen-Chun Chen, Hsinchu (TW)

Correspondence Address: J C PATENTS, INC., 4 VENTURE, SUITE 250, IRVINE, CA, 92618, US

(73) Assignee: RITDISPLAY CORPORATION, Hsinchu (TW)

(21) Appl. No.: 11/564,047

(22) Filed: Nov. 28, 2006

(30) Foreign Application Priority Data
Aug. 8, 2006 (TW) 95129025

(51) Int. Cl. H01L 51/40; H01L 21/00

(52) U.S. Cl. 438/99; 438/29

(57) ABSTRACT

A method for fabricating an active matrix organic electro-luminescence (OEL) display panel is provided. First, a driving circuit array including a plurality of driving circuits is formed on a substrate. A patterned conductive layer is then formed over the driving circuit array, wherein the patterned conductive layer is electrically coupled with a high voltage source and disposed above the driving circuits. Thereafter, a plurality of organic functional layers corresponding to the driving circuits is formed on the patterned conductive layer. Finally, a plurality of cathodes electrically insulated from each other is formed on the organic functional layers, wherein the each cathode is electrically coupled with the one of the driving circuits, respectively.

### CROSS-REFERENCE TO RELATED APPLICATION

This application claims the priority benefit of Taiwan application serial no. 95129025, filed Aug. 8, 2006. All disclosure of the Taiwan application is incorporated herein by reference.

### BACKGROUND OF THE INVENTION

1. Field of the Invention

The present invention relates to a fabricating method of a display panel. More particularly, the present invention relates to a fabricating method of an active matrix organic electro-luminescence (OEL) display panel.

2. Description of Related Art

Currently, information telecommunication industry has become a mainstream industry, especially for those portable communication display products, which have become a focus of the development. Flat-panel displays are communication interfaces between human and information, thus, the development of the flat-panel displays is especially important. The following techniques are currently applied to the flat-panel display: plasma display panel (PDP), liquid crystal display (LCD), electro-luminescent display, light emitting diode (LED), vacuum fluorescent display, field emission display (FED) and electro-chromic display. Compared with other flat-panel display techniques, the organic electro-luminescence display panel has a tremendous application potential to become a mainstream of the next generation of flat-panel displays due to its advantages of self-luminescence, no viewing-angle dependence, saving power, simple manufacturing process, low cost, low working temperature, high response speed and full-color.

FIG. 1 is a circuit diagram of a conventional driving circuit. Referring to FIG. 1, the conventional driving circuit 100 is suitable for driving an organic electro-luminescence device OEL through a high voltage source V_{DD} and a low voltage source V_{cc}. The conventional driving circuit 100 includes a scan line 110, a data line 120 and a control unit 130. The control unit 130 is electrically coupled with the scan line 110, the data line 120 and the high voltage source V_{DD}, and the organic electro-luminescence device OEL is electrically coupled between the control unit 130 and the low voltage source V_{CC}. Generally, the high voltage source V_{DD} is a positive voltage, and the voltage of the low voltage source V_{CC} is generally 0 volt (in a state of being grounded).

As shown in FIG. 1, the control unit 130 in the driving circuit 100 includes two thin film transistors T1, T2 and a capacitor C. The thin film transistor T1 has a gate G1, a source S1 and a drain D1, wherein the gate G1 is electrically coupled with the scan line 110, and the drain D1 is electrically coupled with data line 120. Moreover, the thin film transistor T2 has a gate G2, a source S2 and a drain D2, wherein the gate G2 is electrically coupled with the source S1, and the drain D2 is electrically coupled with the high voltage source V_{DD}, and the source S2 is electrically coupled with the organic electro-luminescence device OEL. It should be noted that, in the conventional driving circuit 100, the capacitor C is electrically coupled between the gate G2 and the drain D2.

When a scan signal V_{SCAN} is transferred to the scan line 110, the thin film transistor T1 is turned on, and at this time, a voltage signal V_{DATA} transferred from the data line 120 is applied on the gate G2 of the thin film transistor T2 through the thin film transistor T1, and the voltage signal V_{DATA} applied on the gate G2 is used to control the current I passing through the thin film transistor T2 and the organic electro-luminescence device OEL, so as to control the desirable luminance to be displayed by the organic electro-luminescence device OEL. When the voltage signal V_{DATA} transferred from the data line 120 is applied on the gate G2, the voltage signal V_{DATA} also charges the capacitor C, and its reference voltage is the high voltage source V_{DD}. In other words, when the voltage signal V_{DATA} is applied on the gate G2, a cross voltage (|V_{DATA}-V_{DD}|) at both terminals of the gate G2 is recorded by the capacitor C. Ideally, when the thin film transistor T1 is turned off, the capacitor C maintains the voltage (V_{DATA}) applied on the gate G2 of the thin film transistor T2 effectively, but in fact, after a long time operation, the voltage V_{S} of the source S2 of the thin film transistor T2 always has drifted upwards, so that the voltage difference V_{gs} between the gate G2 and the source S2 is gradually reduced, and thus causing the luminance to be displayed by the organic electro-luminescence device OEL to be decayed.

In view of the above, the control unit 130 in the driving circuit 100 still cannot stably control the current I passing through the organic electro-luminescence device OEL, and thus, how to make the current I passing through the organic electro-luminescence device OEL be more stable is an important issue in manufacturing an organic electro-luminescence display panel.

### SUMMARY OF THE INVENTION

Accordingly, the present invention is directed to provide a method for fabricating an active matrix organic electro-luminescence (OEL) display panel having stable image quality.

As embodied and broadly described herein, the present invention provides a method for fabricating an active matrix OEL display panel. The method includes following steps. First, a driving circuit array is formed on a substrate, wherein the driving circuit array includes a plurality of driving circuits arranged in array. Then a patterned conductive layer is formed over the driving circuit array, wherein the patterned conductive layer is electrically coupled with a high voltage source and disposed above the driving circuits. After that, a plurality of organic functional layers corresponding to the driving circuits is formed on the patterned conductive layer. Finally, a plurality of cathodes electrically insulated from each other is formed on the organic functional layers, wherein the each cathode is electrically coupled with the one of the driving circuits, respectively.

According to an embodiment of the present invention, the driving circuit array is fabricated by amolphous-silicon thin film transistor (TFT) array process, low temperature polysilicon (LTPS) TFT array process, or organic TFT array process.

According to an embodiment of the present invention, the method for fabricating an active matrix OEL display panel may further include the steps of forming a dielectric layer, wherein the dielectric layer covers the driving circuit array so that the driving circuit array is electrically insulated from the patterned conductive layer.

According to an embodiment of the present invention, the method for forming the patterned conductive layer includes following steps. First, a plurality of strip anodes electrically insulated from each other and a plurality of contact conductors electrically insulated from the strip anodes are formed, wherein the cathodes are electrically coupled with the corresponding driving circuits through the corresponding contact conductors. Next, an anodic bus is formed, and the strip anodes are electrically coupled with each other through the anodic bus.

According to an embodiment of the present invention, the formation method of the patterned conductive layer includes following steps. First, a plurality of strip anodes electrically insulated from each other and a plurality of contact conductors electrically insulated from the strip anodes are formed, wherein the contact conductors are electrically coupled with the corresponding driving circuits. Next, an anodic bus and a plurality of connecting conductors electrically insulated from the anodic bus are formed, wherein the strip anodes are electrically coupled with each other through the anodic bus, and each cathode is electrically coupled with the corresponding driving circuit through the corresponding connecting conductor and contact conductor.

According to an embodiment of the present invention, the method for forming the patterned conductive layer is, for example, forming a common anode and a plurality of contact conductors electrically insulated from the common anode, wherein each cathode is electrically coupled with the corresponding driving circuit through the corresponding contact conductor.

According to an embodiment of the present invention, the fabricating method of an active matrix OEL display panel may further include the formation of a passivation layer, wherein the passivation layer covers the driving circuit array and part of the patterned conductive layer. In an exemplary embodiment of the present invention, the method for forming the organic functional layer and the cathode includes following steps. First, a blocking pattern is formed on the passivation layer, wherein the sidewall of the blocking pattern has an under-cut profile. Next, organic films are sequentially formed on the substrate so as to form an organic functional layer on the patterned conductive layer that is not covered by the passivation layer, and meanwhile, an organic material layer is formed on the blocking pattern. After that, a conductive film is formed on the organic films to form cathodes on the organic functional layers, and meanwhile, to form a conducting material layer on the organic material layer.

According to an embodiment of the present invention, the method for forming the organic functional layer and the cathode includes depositing the organic films and the conductive film with a shadow mask.

According to an embodiment of the present invention, the method for forming the organic functional layer includes following steps. First, a hole transport layer, an OEL layer, and an electron transport layer are formed sequentially on the patterned conductive layer that is not covered by the passivation layer.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a conventional driving circuit.

FIG. 2 is a circuit diagram of a driving circuit according to the present invention.

FIGS. 3A to 3I are schematic flow charts of the process for manufacturing an active matrix organic electro-luminescence display panel according to a first embodiment of the present invention.

FIGS. 4A to 4I are schematic flow charts of the process for manufacturing the active matrix organic electro-luminescence display panel according to a second embodiment of the present invention.

FIGS. 5A to 5H are schematic flow charts of the process for manufacturing the active matrix organic electro-luminescence display panel according to a third embodiment of the present invention.

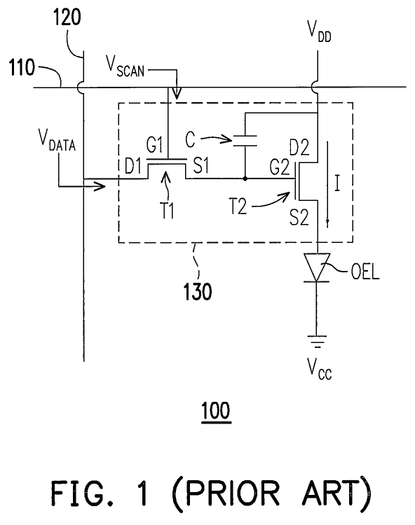

### DESCRIPTION OF EMBODIMENTS

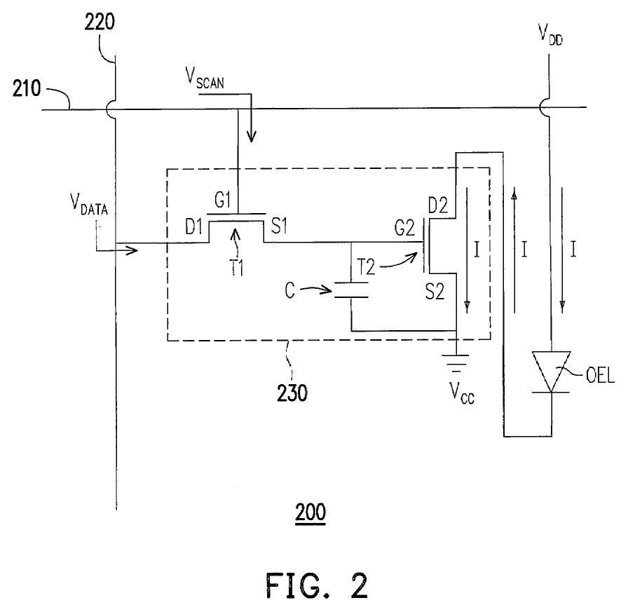

FIG. 2 is a circuit diagram of a driving circuit according to the present invention. Referring to FIG. 2, the driving circuit 200 of the present invention is suitable for driving an organic electro-luminescence device OEL through a high voltage source V_{DD} and a low voltage source V_{CC}. As shown in FIG. 2, the driving circuit 200 includes a scan line 210, a data line 220 and a control unit 230. The control unit 230 is electrically coupled with the scan line 210, the data line 220 and the low voltage source V_{CC}, and the organic electro-luminescence device OEL is electrically coupled between the control unit 230 and the high voltage source V_{DD}. In a preferred embodiment of the present invention, the voltage (V1 volt) provided by the high voltage source V_{DD} is a positive voltage, and the voltage (V2 volt) provided by the low voltage source V_{CC} is a positive voltage or a negative voltage, and V1>V2. Definitely, the low voltage source V_{CC} also may be grounded, i.e., V2=0.

In the driving circuit 200 of the present invention, the control unit 230 can employ various circuit layouts, such as 2T1C architecture and 4T1C architecture. The present invention only takes the 2T1C architecture as an example for illustration, but it is not intended to limit the circuit connection manner to the 2T1C architecture, and those skilled in the art can integrate the driving circuit disclosed in the present invention with a control unit of 4T1C architecture or other architectures.

As shown in FIG. 2, in a preferred embodiment of the present invention, the control unit 230 includes a first thin film transistor T1, a second thin film transistor T2 and a capacitor C. The first thin film transistor T1 has a first gate G1, a first source S1 and a first drain D1, wherein the first gate G1 is electrically coupled with the scan line 210, and the first drain D1 is electrically coupled with the data line 220. The second thin film transistor T2 has a second gate G2, a second source S2 and a second drain D2, wherein the second gate G2 is electrically coupled with the first source S1, the second source S2 is electrically coupled with the low voltage source V_{CC}, and the second drain D2 is electrically coupled with the organic electro-luminescence device OEL. Furthermore, it is clearly known from FIG. 2 that, the organic electro-luninescence device OEL has an anode (+) being electrically coupled with the high voltage source V_{DD} and a cathode being electrically coupled with the second drain D2.

It should be noted that, in the driving circuit 200 of the present invention, the capacitor C is electrically coupled between the second gate G2 and the second source S2, So as to effectively maintain the voltage difference between the second gate G2 and the second source S2, thus avoiding the luminance decay problem caused by the current passing through the organic electro-luminescence device OEL during a long time operation.

In the preferred embodiment of the present invention, the first thin film transistor T1 and the second thin film transistor T2 are amorphous silicon thin film transistors, low-temperature poly-silicon thin film transistors or organic thin film transistors (OTFT). Moreover, the first thin film transistor T1 and the second thin film transistor T2 can be top gate thin film transistors (top gate TFTs) or bottom gate thin film transistors (bottom gate TFTs).

When a scan signal V_{SCAN} is transferred to the scan line 210, the thin film transistor T1 is turned on, and at this time, a voltage signal V_{DATA} transferred from the data line 220 is applied on the gate G2 of the thin film transistor T2 through the thin film transistor T1, and the voltage signal V_{DATA} applied on the gate G2 is used to control the current I passing through the thin film transistor T2 and the organic electro-luminescence device OEL, so as to control the desirable luminance to be displayed by the organic electro-luminescence device OEL. When the voltage signal V_{DATA} transferred from the data line 220 is applied on the second gate G2, the voltage signal V_{DATA} also charges the capacitor C, and its reference voltage is the low voltage source V_{CC}. In other words, when the voltage signal V_{DATA} is applied on the second gate G2, a cross voltage (|V_{DATA}-V_{CC}|) on both terminals of the second gate G2 is recorded by the capacitor C. In the driving circuit of the present invention, when the thin film transistor T1 is turned off, the capacitor C effectively maintains the voltage (V_{DATA}) applied on the second gate G2 of the thin film transistor T2. Moreover, after a long time operation, since the capacitor C is electrically coupled between the second gate G2 and the second source S2, the voltage V_{S} of the second source S2 does not significantly drift upwards. In other words, the voltage difference V_{gs} between the second gate G2 and the second source S2 is not greatly changed, so that the current I passing through the organic electro-luminescence device OEL is effectively controlled, thus, the display quality of the organic electro-luminescence display panel is more stable.

The present invention will be illustrated below in detail through the embodiments, so as to explain how to fabricate the driving circuit 200 in FIG. 2 on an active matrix organic electro-luminescence display panel.

### First Embodiment

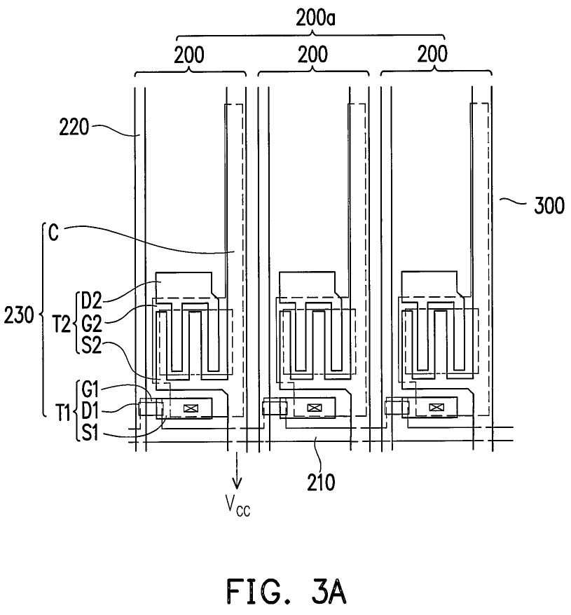

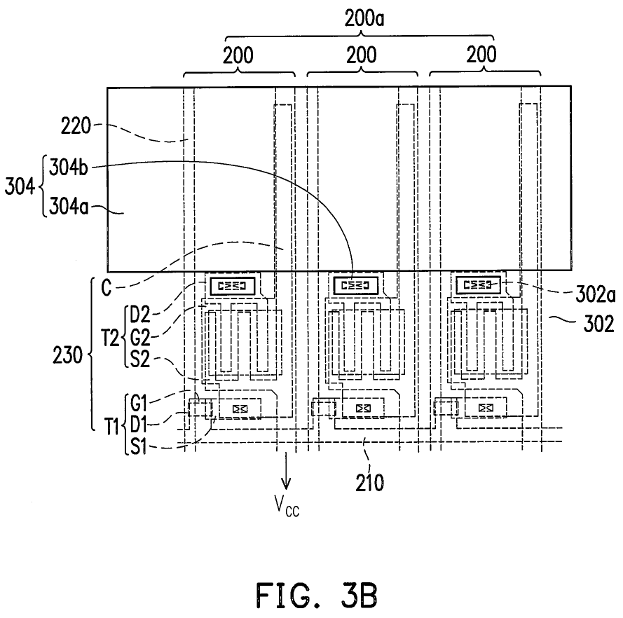

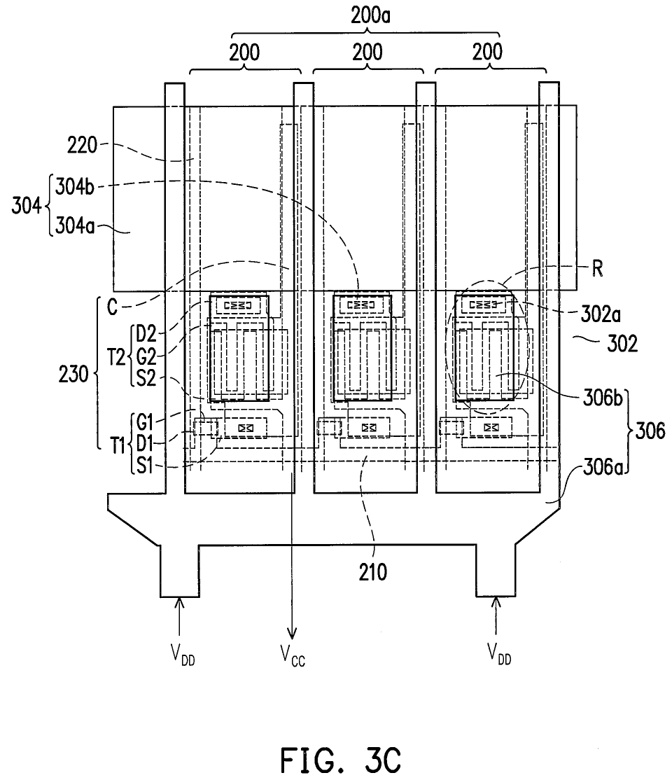

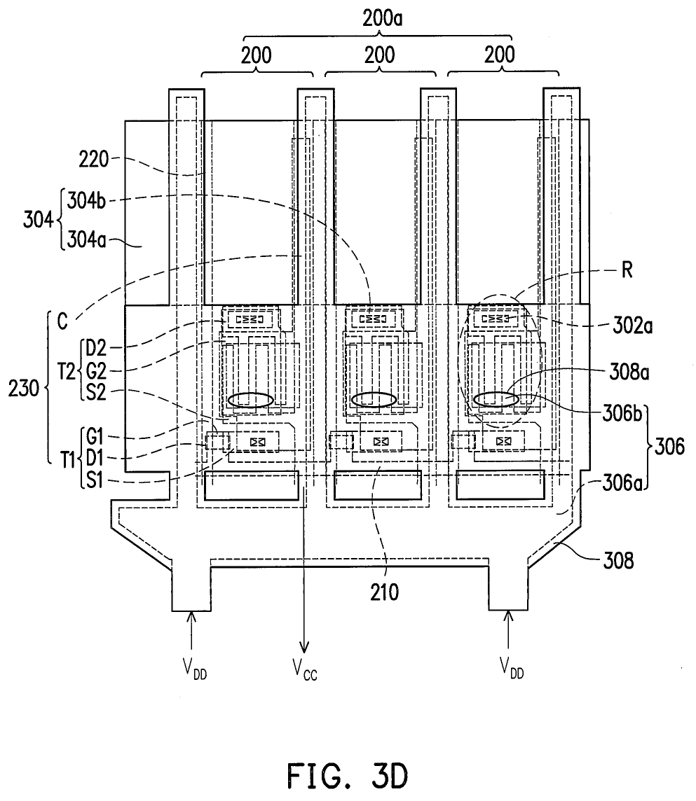

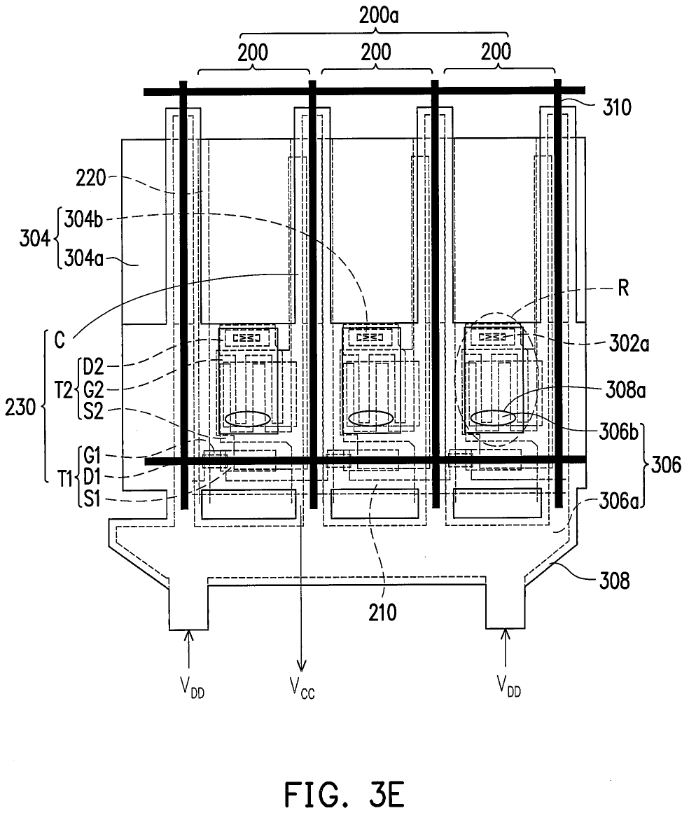

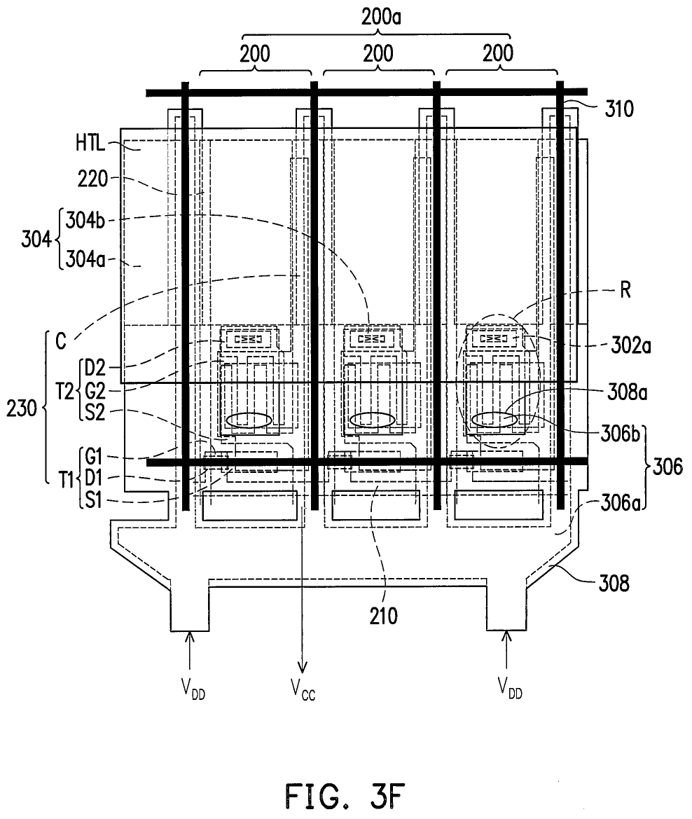

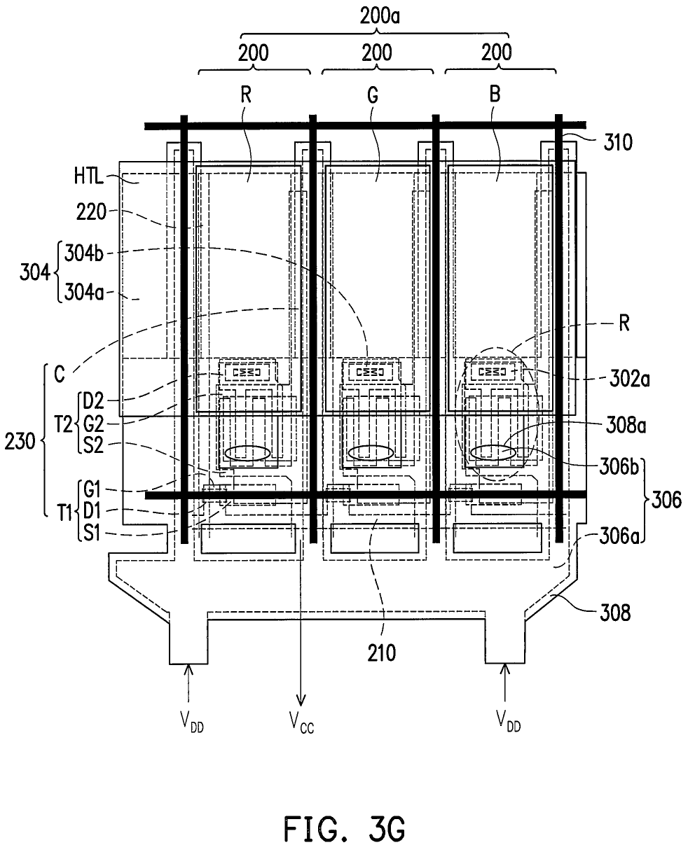

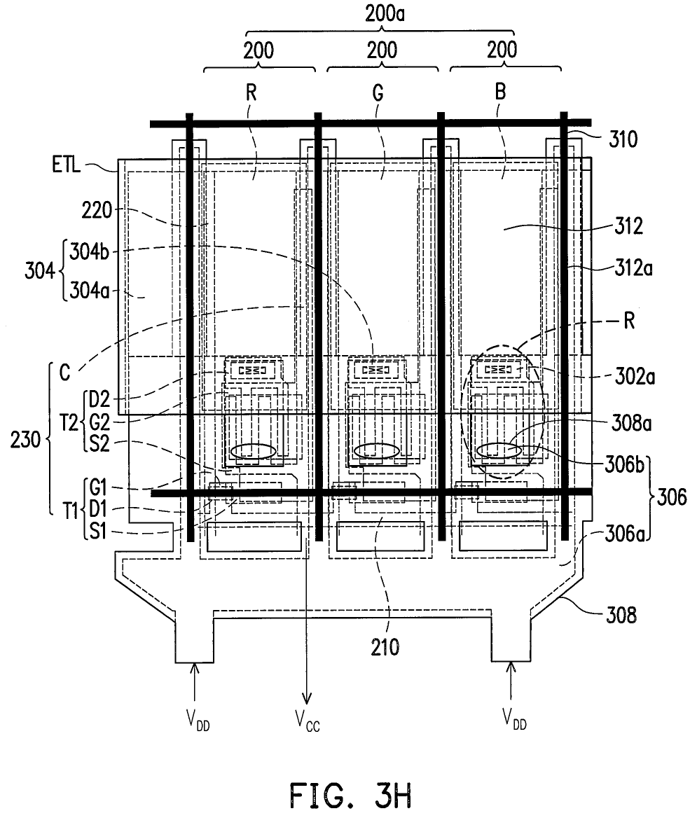

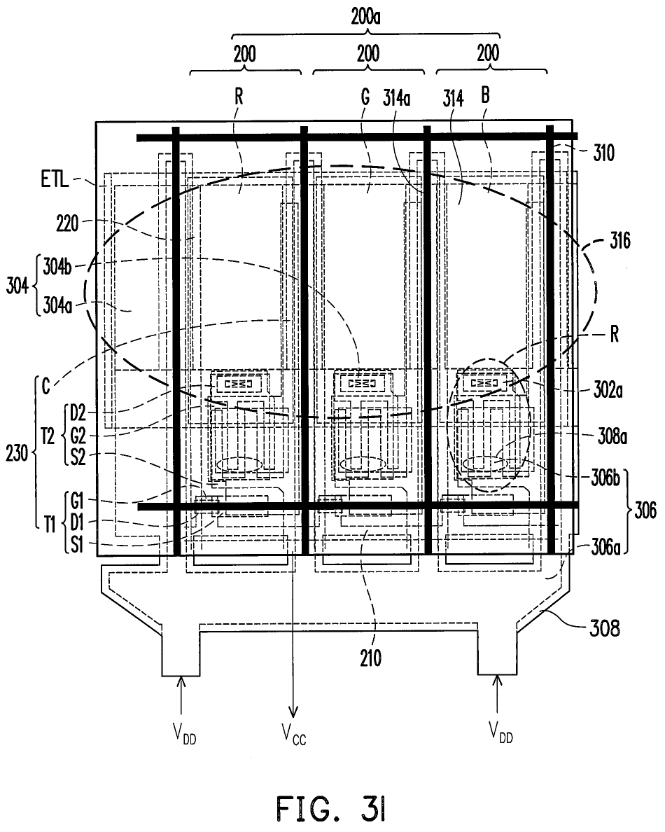

FIGS. 3A to 3I are schematic flow charts of the process for manufacturing an active matrix organic electro-luminescence display panel according to a first embodiment of the present invention. Referring to FIG. 3A, firstly, a substrate 300 is provided, which has a driving circuit array 200a formed thereon. The driving circuit array 200a includes a plurality of driving circuits 200 arranged in array on the substrate 300. The elements in each driving circuit 200 (such as a scan line 210, a data line 220, a control unit 230, a first thin film transistor T1, a second thin film transistor T2, a capacitor C and a low voltage source V_{CC}) and the electrical coupling relationship there-between have already been described in the relevant illustration of FIG. 2, which thus will not be described herein any more.

It should be noted that, the above scan line 210, the data line 220, and the first thin film transistor T1, the second thin film transistor T2 and the capacitor C in the control unit 230 all can be fabricated through the current TFT-array process, such as an amorphous silicon thin film transistor array process, a low-temperature poly-silicon thin film transistor array process or an organic thin film transistor array process.

Referring to FIG. 3B, after the driving circuit array 200a has been formed, a dielectric layer 302 is further formed on the substrate 300 in the present embodiment to cover the driving circuit array 200a. The dielectric layer 302 has a plurality of contact windows 302a corresponding to the second drain D2 to expose a part of the area of the second drain D2. Then, a patterned conductive layer 304 is formed on the dielectric layer 302, wherein the patterned conductive layer 304 includes a plurality of anodes 304a and a plurality of contact conductors 304b respectively coupled with the second drain D2 through the contact windows 302a. It should be noted that, the anode 304a of the present embodiment is a strip-shaped electrode extending along a direction parallel with the extending direction of the scan line 210, and the anode 304a is electrically insulated from the contact conductor 304b. Definitely, the extending direction of the above strip-shaped anode 304a also can be parallel with that of the data line 220, or be designed to other extending directions, which are not limited in the present embodiment. Moreover, the patterned conductive layer 304 is made of, for example, indium tin oxide (ITO), indium zinc oxide (IZO), or other transparent/non-transparent conductive materials.

Referring to FIG. 3C, after the patterned conductive layer 304 has been fabricated, a patterned conductive layer 306 is formed on the dielectric layer 302 and on a part of the area of the patterned conductive layer 304. In the present embodiment, the patterned conductive layer 306 includes an anodic bus 306a and a plurality of connecting conductors 306b electrically coupled with the contact conductor 304b. The anodic bus 306a is electrically coupled with the anodes 304a, so that all the anodes 304a are electrically coupled with the high voltage source V_{DD} simultaneously. As shown in FIG. 3C, the extending direction of the anodic bus 306a is perpendicular to that of the scan line 210, and the anodic bus 306a is electrically insulated from the connecting conductor 306b. Definitely, the extending direction of the anodic bus 306a is changed as the extending direction of the anode 304a changes, but the extending direction is not limited in the present embodiment. Moreover, the patterned conductive layer 306 is made of, for example, metal, alloy or other transparent/non-transparent conductive materials.

As shown in FIG. 3C, the contact conductor 304b is electrically coupled with the connecting conductor 306b, so as to form a so-called re-distribution circuit R. It should be noted that, the re-distribution circuit R formed by the contact conductor 304b and the connecting conductor 306b is used to connect the second drain D2 with a subsequently formed cathode 314 (shown in FIG. 3I).

Referring to FIG. 3D, after the patterned conductive layer 306 has been fabricated, a protective layer 308 is formed to cover the driving circuit 200 and a part of the area of the anode 304a. In the present embodiment, the protective layer 308 covers the re-distribution circuit R and has a plurality of contact windows 308a for exposing a part of the area of the connecting conductor 306b. Furthermore, the protective layer 308 also exposes most of the area (area for displaying) of the anode 304a. Moreover, the protective layer 308 is made of, for example, polyimide, epoxy resin or other materials, and the protective layer 308 mainly aims at protecting the patterned conductive layer 306 from being oxidized or being damaged.

Referring to FIG. 3E, after the protective layer 308 has been fabricated, a blocking pattern 310 is formed on the protective layer 308. In the present embodiment, the blocking pattern 310 is mainly used for defining the position of the subsequently formed cathode 314 (shown in FIG. 3I). Generally, the blocking pattern 310 is made of a dielectric material, and the sidewall of the blocking pattern 310 has an under-cut profile, so that the subsequently formed film layers can be automatically separated into individual film patterns by the blocking pattern 310.

Referring to FIGS. 3F to 3H, after the blocking pattern 310 has been formed, an organic functional layer 312 is formed on the anode 304a. Since the blocking pattern 310 has the function of automatically separating the film layers, an organic material layer 312a is formed on the blocking pattern 310 while the organic functional layer 312 has been formed, and the material of the organic material layer 312a is the same as that of the organic functional layer 312. The organic material layer 312a in the present embodiment includes a plurality of organic films fabricated by way of evaporation or ink jet printing. As shown in FIGS. 3F to 3H, a hole transport layer HTL, organic electro-luminescence layers R, G, B and an electron transport layer ETL are sequentially formed on the anode 304a in the present embodiment.

Referring to FIG. 3I, after the organic functional layer 312 (shown in FIG. 3H) has been formed, cathodes 314 electrically insulated from each other are formed on each organic functional layer 312 (shown in FIG. 3H). Since the blocking pattern 310 has the function of automatically separating the film layer, a conducting material layer 314a is formed on the organic material layer 312a (shown in FIG. 3H) while the cathodes 314 have been formed, and the conducting material layer 314a and the cathodes 314 are made of the same material, for example, the aluminum.

In view of the above, the hole transport layer HTL, organic electro-luminescence layers R, G, B. the electron transport layer ETL and the cathodes 314 are not necessarily patterned through the blocking pattern 310, but patterned through other methods in the present invention, for example, a shadow mask is utilized to define positions for the subsequently formed film layers.

It should be noted that, after the cathodes 314 electrically insulated from each other have been fabricated, each organic electro-luminescence device OEL is considered to be completed, and at this time, the organic electro-luminescence device array 316 formed by arranging the organic electro-luminescence devices OEL thereon is also considered to be completed.

### Second Embodiment

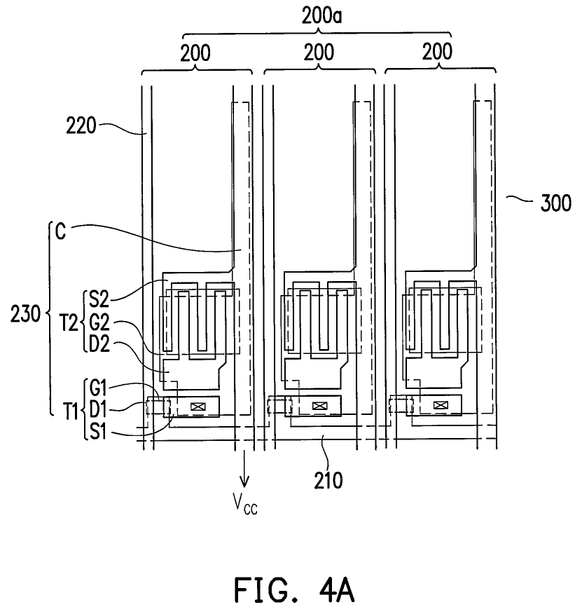

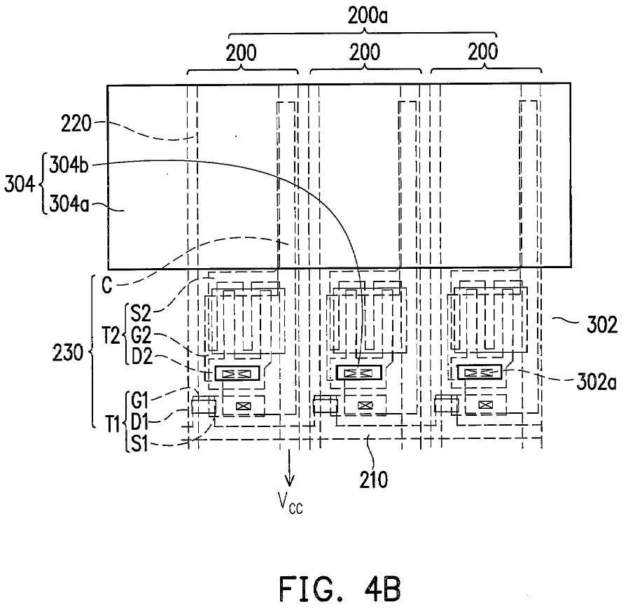

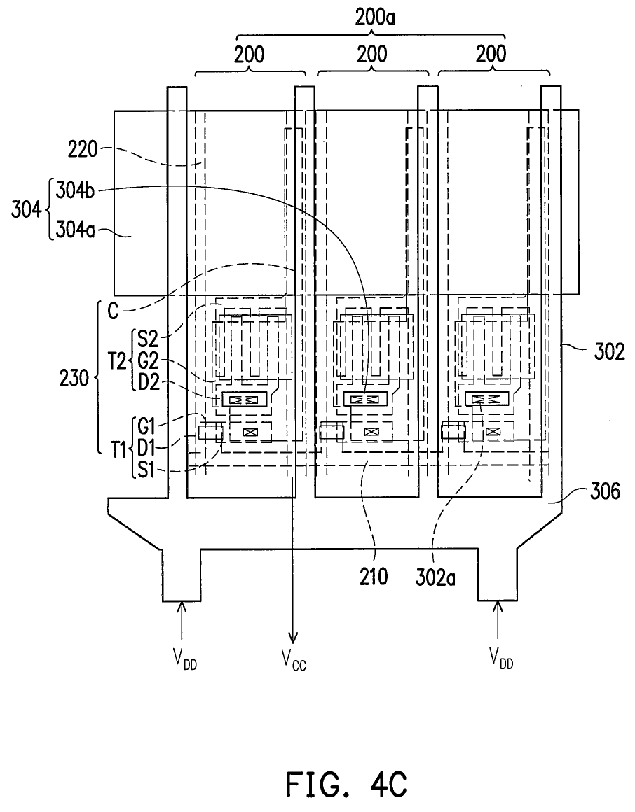

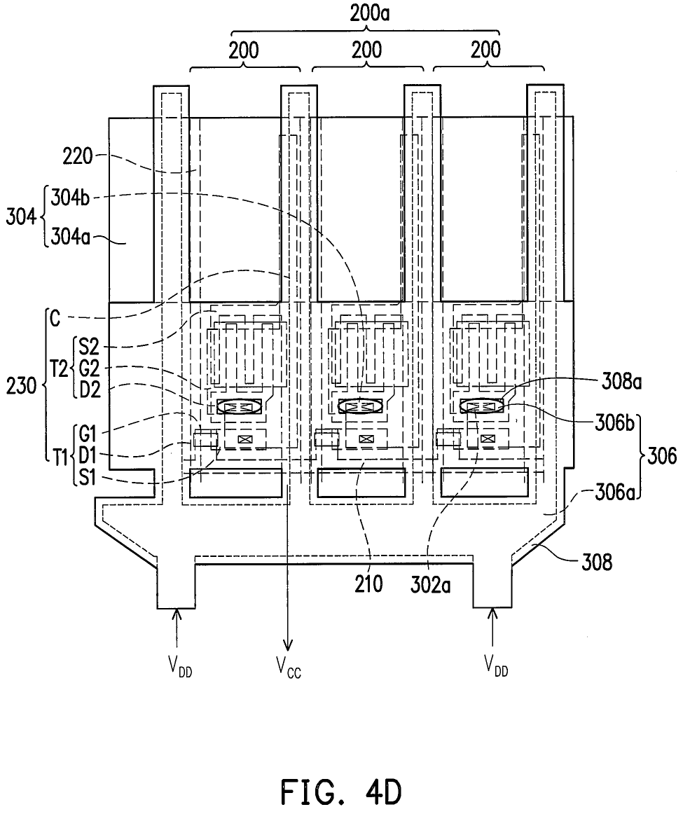

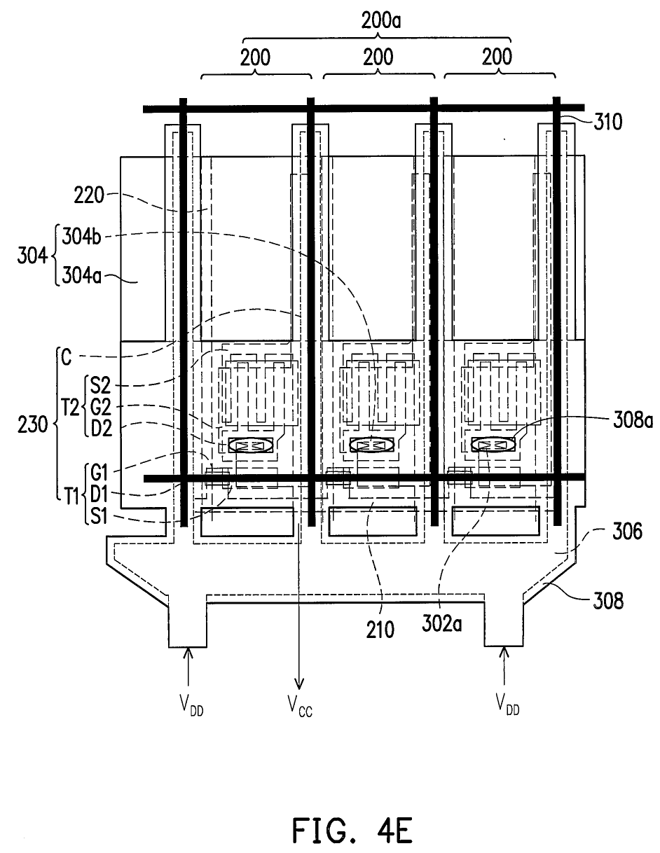

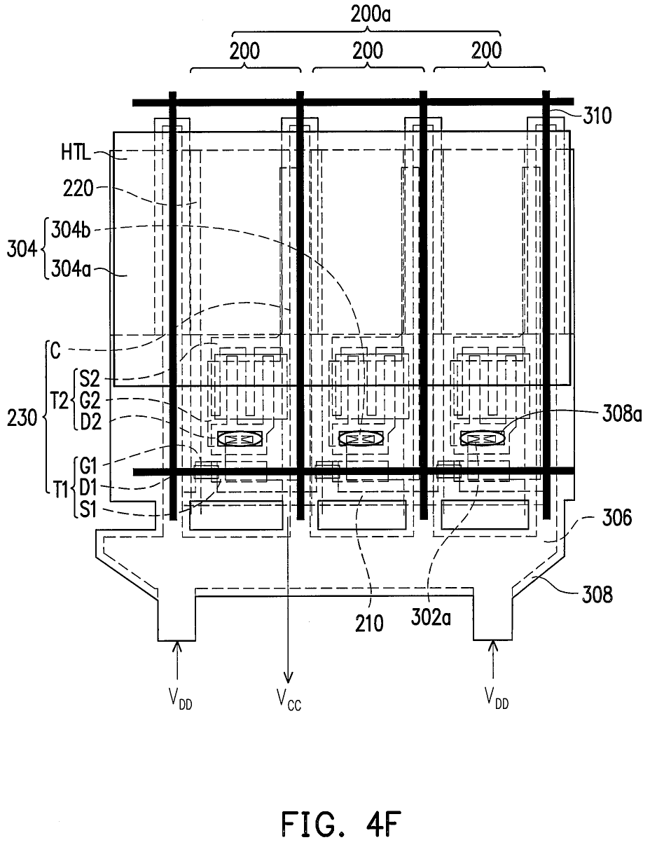

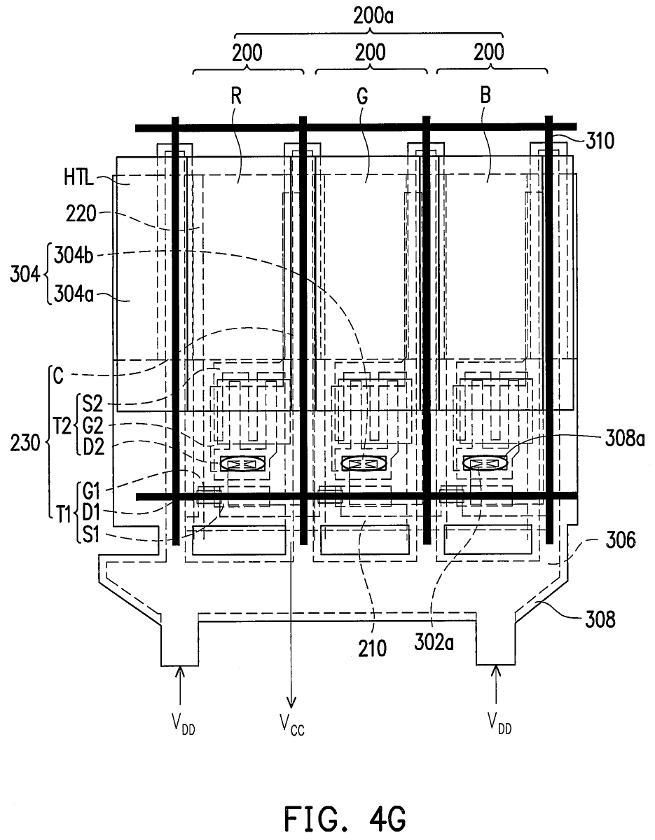

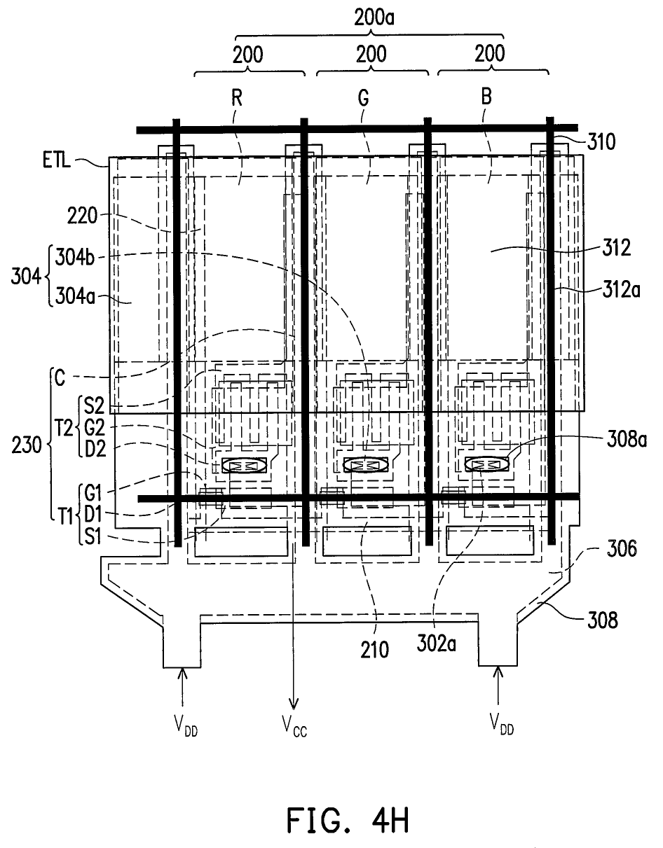

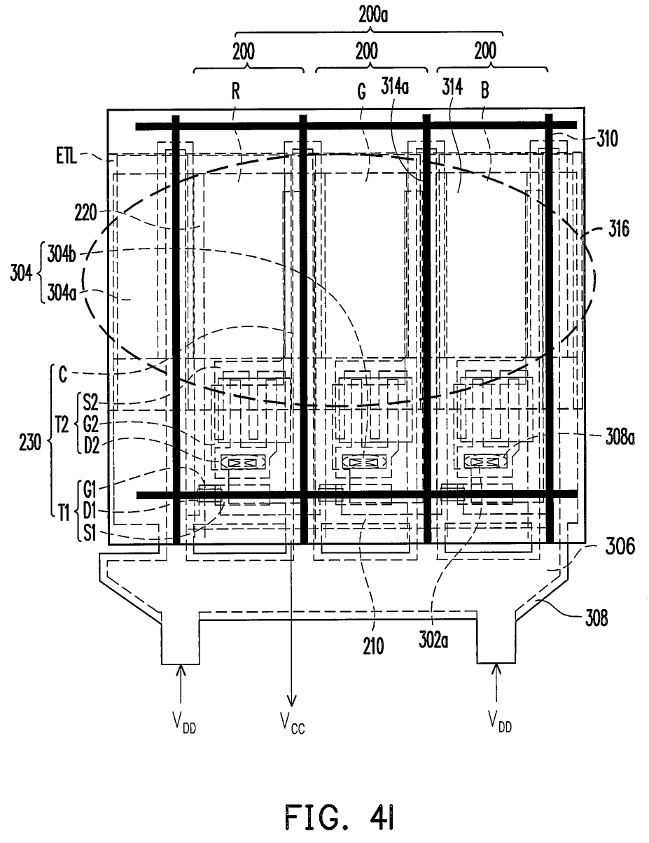

FIGS. 4A to 4I are schematic flow charts of the process for manufacturing the active matrix organic electro-luminescence display panel according to a second embodiment of the present invention. Referring to FIGS. 4A to 4I, the flow of the process for manufacturing the active matrix organic electro-luminescence display panel of the present embodiment is similar to that of the first embodiment, and the main difference there-between lies in the procedures of FIG. 4A and FIG. 4C.

As shown in FIG. 4A, the present embodiment mainly directs to modifying the layout of the second thin film transistor T2, so as to omit the fabrication of the connecting conductor 306b in FIG. 3C. Specifically, the positions of the second source S2 and the second drain D2 in the first embodiment are exchanged in the present embodiment, so that the second drain D2 can be positioned far away from the anode 304a, without being covered by the subsequently formed organic electro-luminescence device OEL.

### Third Embodiment

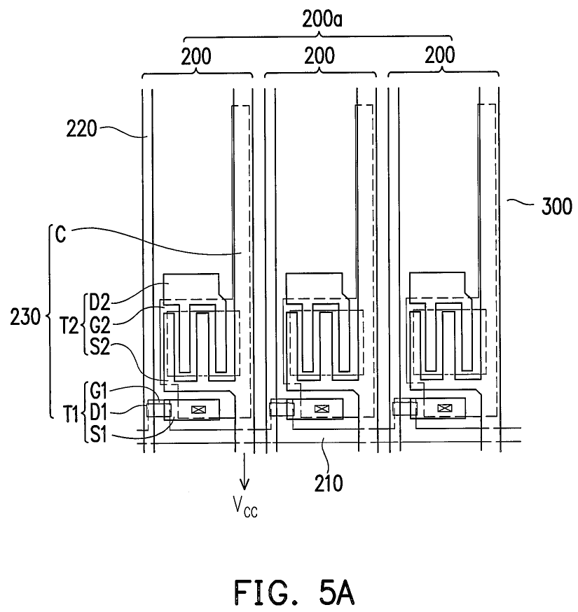

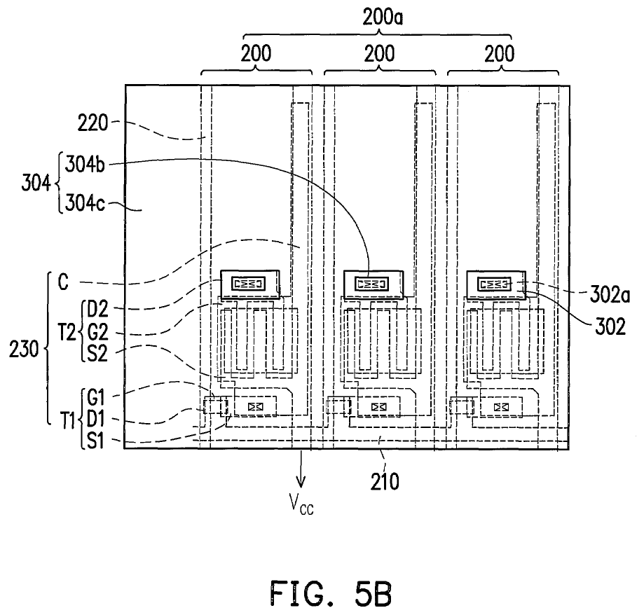

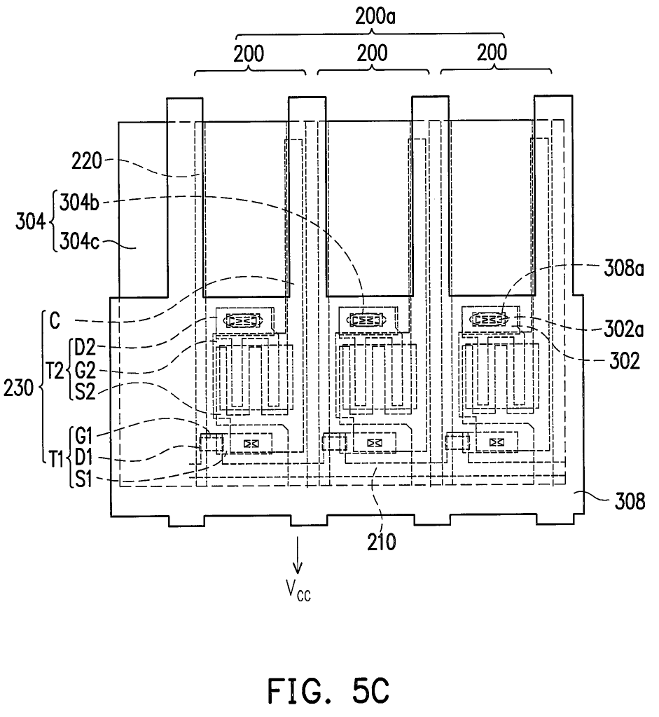

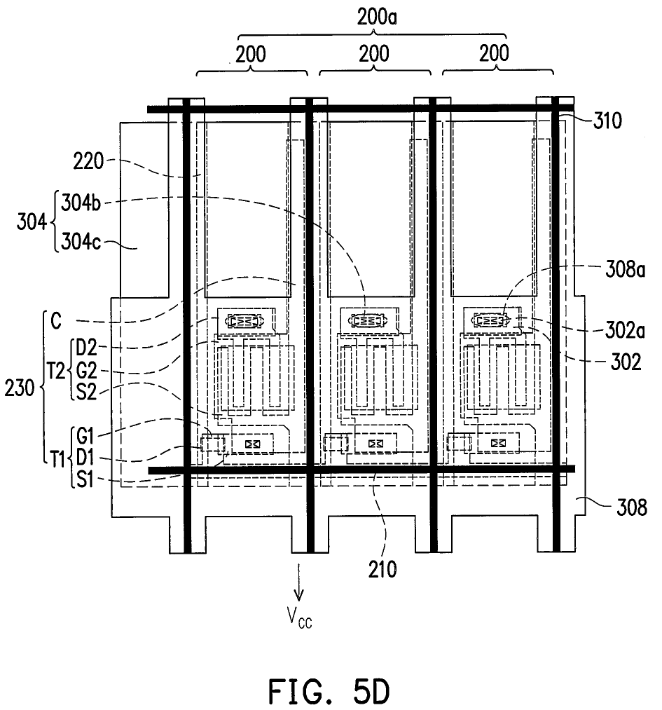

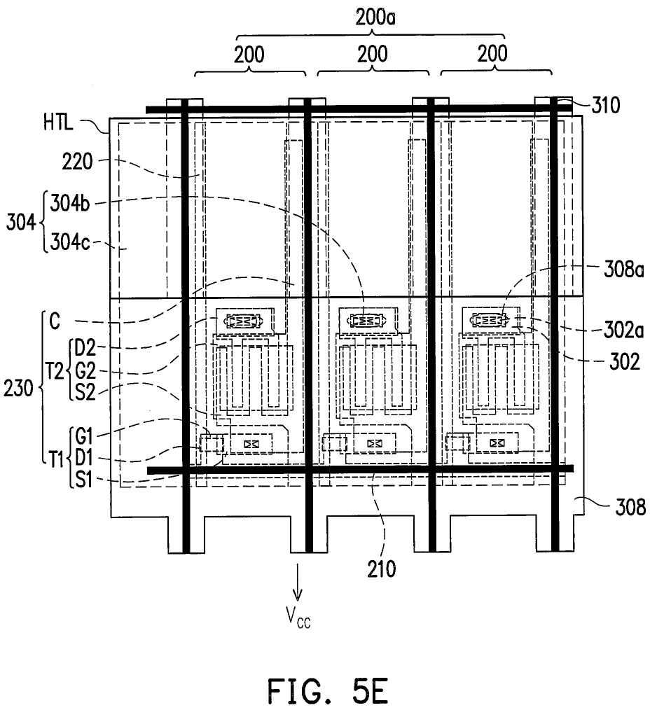

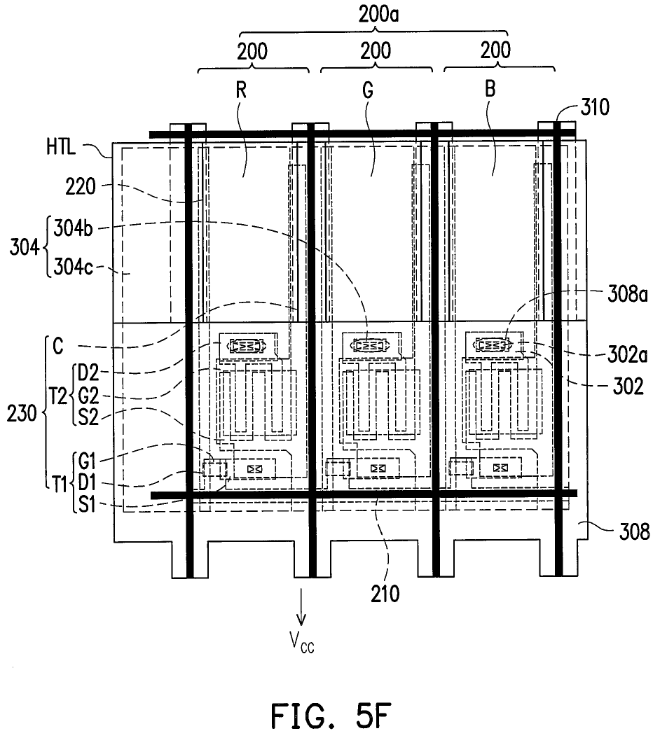

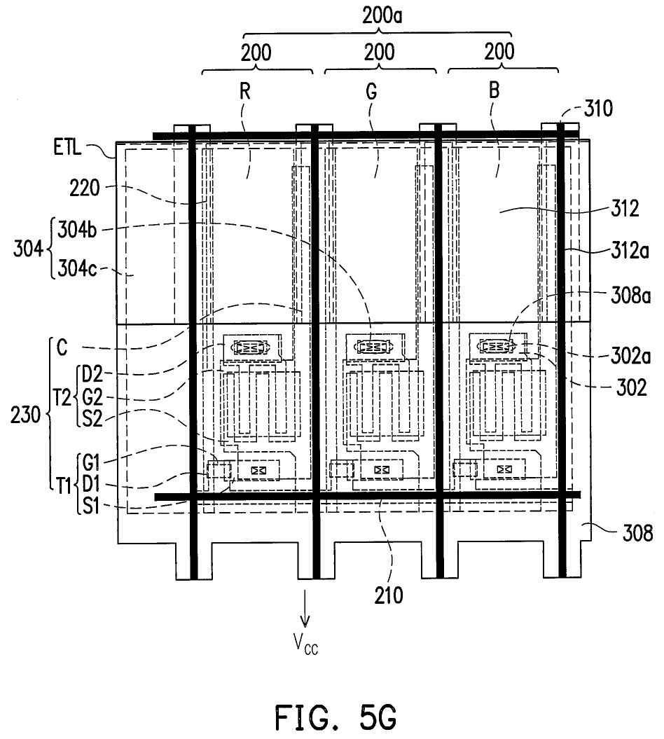

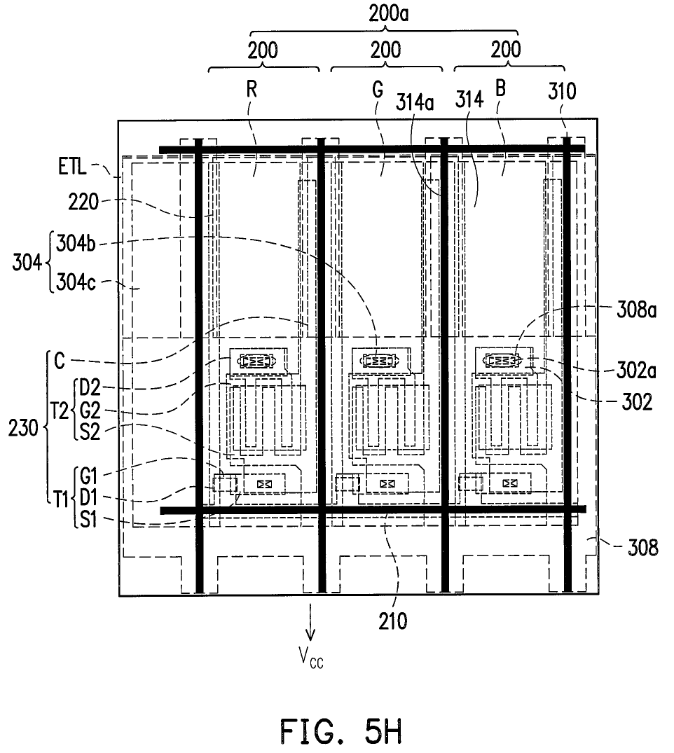

FIGS. 5A to 5H are schematic flow charts of the process for manufacturing the active matrix organic electro-luminescence display panel according to a third embodiment of the present invention. Referring to FIGS. 5A to 5H, the flow for manufacturing an active matrix organic electro-luminescence display panel of the present embodiment is similar to that of the first embodiment, and the main difference there-between lies in the procedures of FIG. 5B and FIG. 5C.

As shown in FIG. 5B, the present embodiment mainly directs to modifying the pattern of the strip-shaped anode 304a, so as to omit the fabrication of the anodic bus 306a and the connecting conductor 306b in FIG. 3C. Specifically, the strip-shaped anode 304a in the first embodiment is modified to a common anode 304c in the present embodiment. Since the common anode 304c can be served as an anode for all the organic electro-luminescence devices OEL, the anodic bus 306a and the connecting conductor 306b in FIG. 3C are not necessarily fabricated in the present embodiment.

As shown in FIGS. 3I, 4I and 5H, the active matrix organic electro-luminescence display panel of the present invention includes a substrate 300, an organic electro-luminescence device array 316 and a driving circuit 200a. The organic electro-luminescence device array 316 includes a plurality of organic electro-luminescence device OEL arranged in array on the substrate 300. The driving circuit array 200a includes a plurality of driving circuits 200 arranged in array on the substrate 300, and the driving circuit 200 is suitable for driving the corresponding organic electro-luminescence device OEL through a high voltage source V_{DD} and a low voltage source V_{CC}. Furthermore, each driving circuit 200 includes a scan line 210, a data line 220 and a control unit 230. The control unit 230 is electrically coupled with the scan line 210, the data line 220 and the low voltage source V_{CC}, and the corresponding organic electro-luminescence device OEL is electrically coupled between the control unit 230 and the high voltage source V_{DD}.

In overview, the driving circuit and active matrix OEL display panel in the present invention have at least following advantages:

1. The driving circuit of the present invention effectively stabilizes the driving current passing through the organic electro-luminescence device, so the present invention makes the active matrix organic electro-luminescence display panel achieve a preferable display quality.

2. The active matrix organic electro-luminescence display panel of the present invention is compatible with the current manufacturing process, which will not cause an excessive burden on the manufacturing cost.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A method for fabricating an active matrix organic electro-luminescence (OEL) display panel, the method comprising:
forming a driving circuit array on a substrate, wherein the driving circuit array comprises a plurality of driving circuits arranged in array;
forming a patterned conductive layer over the driving circuit array, wherein the patterned conductive layer is electrically coupled with a high voltage source and disposed above the driving circuits;
forming a plurality of organic functional layers corresponding to the driving circuits on the patterned conductive layer; and
forming a plurality of cathodes electrically insulated from each other on the organic functional layers, wherein each of the cathodes is electrically coupled with the one of the driving circuits, respectively.

2. The fabricating method as claimed in claim 1, wherein the driving circuit array is fabricated by amorphous-silicon thin film transistor (TFT) array process, low temperature polysilicon (LTPS) TFT array process, or organic TFT array process.

3. The fabricating method as claimed in claim 1, further comprising forming a dielectric layer, wherein the dielectric layer covers the driving circuit array so that the driving circuit array is electrically insulated from the patterned conductive layer.

4. The fabricating method as claimed in claim 1, wherein a method for forming the patterned conductive layer comprises:
forming a plurality of strip anodes electrically insulated from each other and a plurality of contact conductors electrically insulated from the strip anodes, wherein each of the cathodes is electrically coupled with the corresponding driving circuit through the corresponding contact conductor; and
forming an anodic bus, wherein the strip anodes are electrically coupled with each other through the anodic bus.

5. The fabricating method as claimed in claim 1, wherein a method for forming the patterned conductive layer comprises:
forming a plurality of strip anodes electrically insulated from each other and a plurality of contact conductors electrically insulated from the strip anodes, wherein each of the contact conductors is electrically coupled with the corresponding driving circuit; and
forming an anodic bus and a plurality of connecting conductors electrically insulated from the anodic bus, wherein the strip anodes are electrically coupled with each other through the anodic bus, and each of the cathodes is electrically coupled with the corresponding driving circuit through the corresponding connecting conductor and contact conductor.

6. The fabricating method as claimed in claim 1, wherein a method for forming the patterned conductive layer comprises:
forming a common anode and a plurality of contact conductors electrically insulated from the common anode, wherein each of the cathodes is electrically coupled with the corresponding driving circuit through the corresponding contact conductor.

7. The fabricating method as claimed in claim 1, further comprising forming a passivation layer, wherein the passivation layer covers the driving circuit array and part of the patterned conductive layer.

8. The fabricating method as claimed in claim 7, wherein a method for forming the organic functional layers and the cathodes comprises:
forming a blocking pattern on the passivation layer, wherein the sidewall of the blocking pattern has an under-cut profile.
forming organic films on the substrate to form the organic functional layers on the patterned conductive layer that is not covered by the passivation layer, and forming an organic material layer on the blocking pattern simultaneously; and
forming a conductive film on the organic films to form the cathodes on the organic functional layers, and forming the conducting material layer on the organic material layer simultaneously.

9. The fabricating method as claimed in claim 1, wherein a method for forming the organic functional layers and the cathodes comprises forming the organic films and the conductive films with a shadow mask.

10. The fabricating method as claimed in claim 1, wherein a method for forming each of the organic functional layers comprises:
forming a hole transport layer on the patterned conductive layer that is not covered by the passivation layer;
forming an OEL layer on the hole transport layer; and
forming an electron transport layer on the OEL layer.
